(19) United States
(12) Patent Application Publication
(10) Pub. No.: US 2020/0243564 A1
(43) Pub. Date: Jul. 30, 2020

(54) METHOD FOR REPAIRING SUBSTRATE AND ELECTRONIC DEVICE

(71) Applicant: InnoLux Corporation, Miao-Li County (TW)

(72) Inventors: Ming-Chuan WANG, Miao-Li County (TW); Shang-Yen TSAI, Miao-Li County (TW); Wei-Hang CHANG, Miao-Li County (TW)

(21) Appl. No.: 16/729,911

(22) Filed: Dec. 30, 2019

(30) Foreign Application Priority Data
Jan. 30, 2019 (CN) 201910090462.X

(51) Int. Cl. H01L 27/12; H01L 21/768; H01L 21/66

(52) U.S. Cl. CPC H01L 27/124; H01L 21/76894; H01L 22/20; H01L 21/76877; H01L 27/1259; H01L 21/76805

(57) ABSTRACT

A method for repairing a substrate and an electronic device are disclosed, wherein the electronic device includes: a substrate; a patterned metal layer disposed on the substrate, and the patterned metal layer including a first metal section and a second metal section which is disconnected to the first metal section, wherein at least one of the first metal section and the second metal section has a through hole; and a first conductive layer electrically connected to one of the first metal section and the second section by the through hole; wherein the first conductive layer has a protrusion, the protrusion locating outside the through hole.

### CROSS REFERENCE TO RELATED APPLICATION

This application claims the benefits of the Chinese Patent Application Serial Number 201910090462.X, filed on Jan. 30, 2019, the subject matter of which is incorporated herein by reference.

### BACKGROUND

### 1. Field of the Disclosure

The present disclosure relates to a method for repairing substrates and an electronic device and, more particularly, to a method for repairing wire breakage of the substrates and an electronic device.

### 2. Description of Related Art

Generally, a thin film transistor (TFT) substrate includes a scan line for providing a scan signal and a data line for providing a data signal. The occurrence of wire breakage is inevitable during the manufacturing process of the TFT substrate, which affects the display quality. If the wire breakage defect exists in the TFT substrate, the display device will be discarded, leading to an increase in cost.

In order to lower the manufacturing cost, the completed TFT substrate will be inspected, and the identified wire breakage will be repaired to reduce the discarded display device. However, the repair for wire breakage still has defects of high impedance or low reliability, so that the repair success rate for wire breakage cannot be effectively improved.

Therefore, it is imperative to provide a method for repairing wire breakage of the substrates to achieve low impedance, high reliability or high repair success rate.

### SUMMARY

In light of the above, the present disclosure provides a method for repairing substrates and an electronic device, such that the repaired section achieves low impedance, high reliability or high repair success rate.

In order to achieve the above and other objectives, the present disclosure provides an electronic device, comprising: a substrate; a patterned metal layer disposed on the substrate, and the patterned metal layer comprises a first metal section and a second metal section disconnected to the first metal section, wherein at least one of the first metal section and the second metal section has a through hole; and a first conductive layer electrically connected to one of the first metal section and the second metal section by the through hole; wherein, the first conductive layer has a protrusion locating outside the through hole.

The present disclosure further provides an electronic device, comprising: a substrate; a patterned metal layer disposed on the substrate, and the patterned metal layer comprises a first metal section and a second metal section disconnected to the first metal section, wherein at least one of the first metal section and the second metal section has a through hole; and a second conductive layer, and at least a portion of the second conductive layer is disposed in the through hole; and a third conductive layer disposed on the second conductive layer, and at least a portion of the third conductive layer is disposed in the through hole; wherein the second conductive layer is electrically connected to the first metal section or the second metal section.

The present disclosure further provides a method for repairing substrates, comprising: providing a substrate having a patterned metal layer disposed thereon; identifying a first metal section and a second metal section disconnected to the first metal section in the patterned metal layer; illuminating at least one of the first metal section and the second metal section with laser to form at least one through hole in at least one of the first metal section and the second metal section; forming a second conductive layer, at least a portion of the second conductive layer is disposed in the through hole, and the second conductive layer is electrically connected to the first metal section or the second metal section; and forming a third conductive layer on the second conductive layer, and at least a portion of the third conductive layer is disposed in the through hole.

### BRIEF DESCRIPTION OF THE DRAWINGS

FIG. 1 is a block diagram of a method for repairing substrates according to an embodiment of the present disclosure.

FIG. 2 is a block diagram of a method for repairing substrates according to another embodiment of the present disclosure.

FIG. 3 is a schematic view of substrate repair according to the present disclosure.

FIG. 4A is a cross-sectional view taken along line X-X′ of FIG. 3.

FIG. 4B is a cross-sectional view taken along line Y-Y′ of FIG. 3.

FIG. 4C is a cross-sectional view taken along line Z-Z′ of FIG. 3.

FIG. 5 is a scanning electron microscope (SEM) image showing the cross-section of an electronic device according to an embodiment of the present disclosure.

FIG. 6 is a scanning electron microscope (SEM) image showing the cross-section of an electronic device according to another embodiment of the present disclosure.

FIG. 7 is a scanning electron microscope (SEM) image showing a top view of a through hole according to an embodiment of the present disclosure.

### DETAILED DESCRIPTION

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

Ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. The ordinal numbers are only intended to distinguish a component with a name from another component with the same name.

A directive term, such as “on,” used herein may refer to two components in direct contact with each other or refer to two components not in direct contact with each other. Likewise, a directive term, such as “under,” used herein may refer to two components in direct contact with each other or refer to two components not in direct contact with each other.

The present disclosure is hereunder illustrated by exemplary embodiments, but the present disclosure is not limited thereto. Instead, the present disclosure may combine with any other known structures to create any new embodiment.

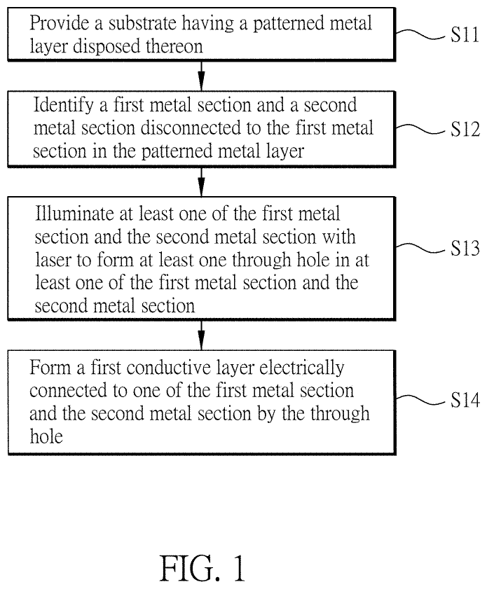

FIG. 1 is a block diagram of a method for repairing substrates according to an embodiment of the present disclosure. First, referring to step S11 of FIG. 1, a substrate is provided such that a patterned metal layer is disposed thereon. The patterned metal layer comprises a first metal section and a second metal section disconnected to the first metal section. Step S12 refers to identifying a first metal section and a second metal section disconnected to the first metal section in the patterned metal layer. Step S13 refers to illuminating at least one of the first metal section and the second metal section with laser in order to form at least one through hole in at least one of the first metal section and the second metal section. Herein, the present disclosure is not restrictive of the wavelength, illuminating duration, or temperature of the laser; the present disclosure is not restrictive of the shape or size of the through hole; and all of which are subject to changes as needed. Step S14 refers to forming a first conductive layer electrically connected to one of the first metal section and the second metal section by the through hole; wherein, the first the first conductive layer has a protrusion locating outside the through hole. By the method for repairing substrates described in the present disclosure, the first metal section and the second metal section disconnected to the first metal section can be electrically connected to conduct a disconnecting area.

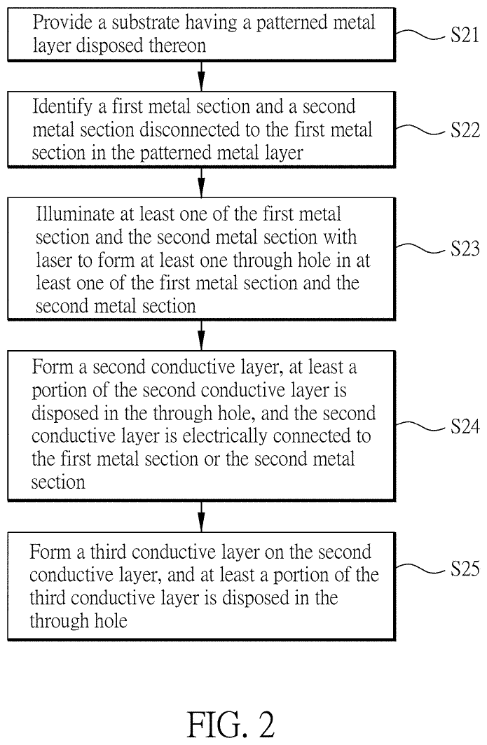

FIG. 2 is a block diagram of a method for repairing substrates according to another embodiment of the present disclosure. The method of FIG. 2 is similar to that of FIG. 1.

Referring to step S21 of FIG. 2, a substrate is provided such that a patterned metal layer is disposed thereon. The patterned metal layer comprises a first metal section and a second metal section disconnected to the first metal section. Step S22 refers to identifying a first metal section and a second metal section disconnected to the first metal section in the patterned metal layer. Step S23 refers to illuminating at least one of the first metal section and the second metal section with laser in order to form at least one through hole in at least one of the first metal section and the second metal section. Herein, the present disclosure is not restrictive of the wavelength, illuminating duration, or temperature of the laser; the present disclosure is not restrictive of the shape or size of the through hole; and all of which are subject to changes as needed. Step S24 refers to forming a second conductive layer, at least a portion of the second conductive layer is disposed in the through hole, and the second conductive layer is electrically connected to the first metal section or the second metal section. Step S25 refers to forming a third conductive layer on the second conductive layer, and at least a portion of the third conductive layer is disposed in the through hole. In the method for repairing substrates, the first metal section and the second metal section disconnected to the first metal section can be electrically connected with each other by multiple conductive layers in order to conduct a disconnected area.

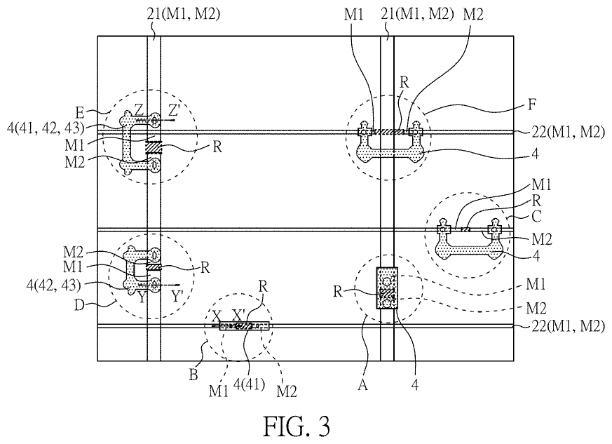

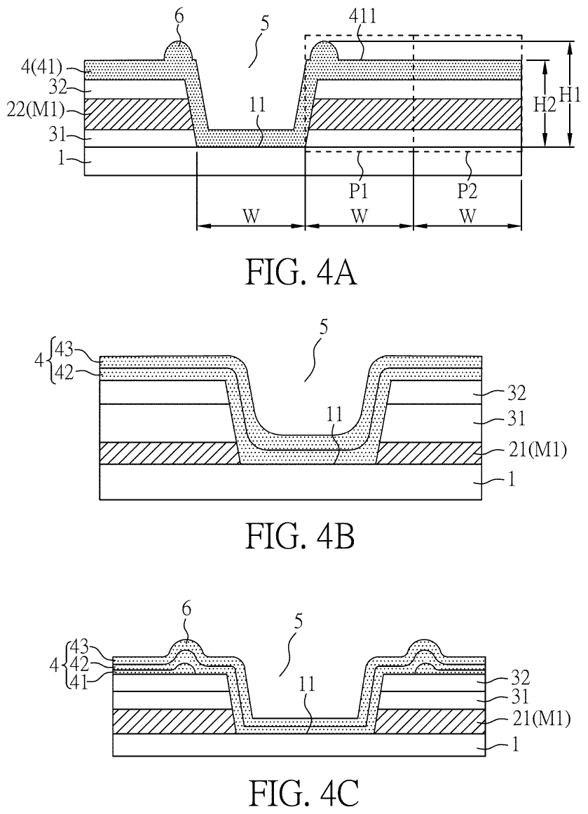

FIG. 3 is a schematic view of substrate repair according to the present disclosure, wherein the repair can be performed by applying the method for repairing substrate shown in FIG. 1 or FIG. 2. FIG. 4A is a cross-sectional view taken along line X-X′ of FIG. 3; FIG. 4B is a cross-sectional view taken along line Y-Y′ of FIG. 3: FIG. 4C is a cross-sectional view taken along line Z-Z′ of FIG. 3.

First, the substrate repair is performed using the method shown in FIG. 1. As shown in FIG. 3 and FIG. 4A, in step S11, a substrate 1 is provided such that a patterned metal layer (including a first patterned metal layer 21 and/or a second patterned metal layer 22) can be sequentially disposed thereon. In addition, in the present embodiment, a first insulating layer 31 is further disposed between the substrate 1 and the second patterned metal layer 22, and a second insulating layer 32 is disposed on the second patterned metal layer 22. However, the present disclosure is not limited thereto. For instance, other insulating layers or metal layers can be disposed between the substrate 1 and the first patterned metal layer 21, and a planar layer or a passivation layer can be disposed on the second insulating layer 32. In step S12, it relates to identifying a first metal section M1 and a second metal section M2 disconnected to the first metal section M1 in the patterned metal layer (including a first patterned metal layer 21 and a second patterned metal layer 22). Herein, said “first metal section M1 and a second metal section M2 disconnected to the first metal section M1” refers that a disconnected area R exists between the first metal section M1 and the second metal section M2, such that the first metal section M1 and the second metal section M2 are not electrically connected. In an embodiment of the present disclosure, the patterned metal layer (including a first patterned metal layer 21 and a second patterned metal layer 22) can comprise a plurality of disconnected areas R. More specifically, the patterned metal layer (including a first patterned metal layer 21 and a second patterned metal layer 22) can comprise at least one first metal section M1 and at least one second metal section M2, which are alternately arranged and disconnected. However, the present disclosure is not limited thereto. Afterward, in step S13, it illuminates at least one of the first metal section M1 and the second metal section M2 with laser, rendering forming at least one through hole 5 in at least one of the first metal section M1 and the second metal section M2. Then, in step S14 a first conductive layer 41 is formed and electrically connected with one of the first metal section M1 and the second metal section M2 by the through hole 5. In the through hole 5, the portion of the first conductive layer 41 can be in contact with the substrate surface 11.

In the present embodiment, the substrate repair can be performed using the method shown in FIG. 2; wherein, steps S21 to S23 of FIG. 2 are similar to steps S11 to S13 of FIG. 1, and thus the details are omitted. In step S24 following the step S23, a second conductive layer 42 is formed, at least a portion of the second conductive layer 42 is disposed in the through hole 5, and the second conductive layer 42 is electrically connected with the first metal section M1 or the second metal section M2, as shown in FIG. 3 and FIG. 4B. In step S25, a third conductive layer 43 is formed on the second conductive layer 42, and at least a portion of the third conductive layer 43 is disposed in the through hole 5. In the through hole 5, the portion of the second conductive layer 42 can be in contact with substrate surface 11.

As described above, the first patterned metal layer 21 or the second patterned metal layer 22 can be electrically connected with the disconnected area R when the first patterned metal layer 21 or the second patterned metal layer 22 has a defect of disconnected area R, such that the effect of conducting the disconnected area R is achieved. In other words, when the first patterned metal layer 21 or second patterned metal layer 22 comprises a first metal section M1 and a second metal section M2 disconnected to the first metal section M1, the first metal section M1 or second metal section M2 can be electrically connected with the conductive layer 4.

More specifically, as shown in FIG. 3, the first patterned metal layer 21 or the second patterned metal layer 22 can electrically connect the first metal section M1 with the second metal section M2 by the conductive layer 4 completely overlapping the disconnected area R (as shown in the disconnected positions A and B of FIG. 3), in a top view. The first patterned metal layer 21 or second patterned metal layer 22 can electrically connect the first metal section M1 with the second metal section M2 by the conductive layer 4 which does not overlap the disconnected area R, as shown in the disconnected positions C and D of FIG. 3. Alternatively, the first patterned metal layer 21 can electrically connect the first metal section M1 with the second metal section M2 by the conductive layer 4 that overlaps a portion of the second patterned metal layer 22 in the top view, as shown in the disconnected position E of FIG. 3. Similarly, the second patterned metal layer 22 can electrically connect the first metal section M1 with the second metal section M2 by the conductive layer 4 that overlaps a portion of the first patterned metal layer 21 in the top view, as shown in the disconnected position F of FIG. 3. However, the present disclosure is not limited thereto.

In the present disclosure, the substrate 1 can be a rigid substrate, flexible substrate or film. The material of the substrate 1 can include, for example, quartz, glass, silicon wafer, sapphire or other inorganic materials; polycarbonate (PC), polyimide (P1), polypropylene (PP), polyethylene terephthalate (PET), other plastic materials, other polymer materials or other organic material. However, the present disclosure is not limited thereto.

In the present disclosure, the first patterned metal layer 21 and the second patterned metal layer 22 can be made of the same or different materials, and the materials of the first patterned metal layer 21 and the second patterned metal layer 22 can include, for example, copper, molybdenum, aluminum, titanium, other suitable metals or combinations thereof. However, the present disclosure is not limited thereto. In addition, the first patterned metal layer 21 and the second patterned metal layer 22 can include a plurality of metal layers, and the materials of the plurality of metal layers may respectively comprise copper, molybdenum, aluminum, titanium, other suitable metals or a combination thereof. However, the present disclosure is not limited thereto.

In the present disclosure, the first insulating layer 31 and the second insulating layer 32 can be made of the same or different materials. The materials of the first insulating layer 31 and the second insulating layer 32 can comprise, for example, silicon nitride, silicon oxide, aluminum oxide, silicon oxynitride, polymer, photoresist, other suitable materials or a combination thereof. However, the present disclosure is not limited thereto.

In the present disclosure, the conductive layer 4 can comprise a single-layer or multi-layer structure, and the material of the conductive layer 4 can comprise, for example, silver, gold, tungsten, other suitable metal materials or a combination thereof. However, the present disclosure is not limited thereto. In addition, the conductive layer 4 can be substantially a linear structure as shown in the disconnected positions A and B of FIG. 3; the conductive layer 4 can be substantially a U-shaped structure as shown in the disconnected positions C to F of FIG. 3; or, the conductive layer 4 can be an arc structure or irregular structure. However, the present disclosure is not limited thereto.

Details of various embodiments of the conductive layer 4 will be described below, and the following embodiments serve exemplary purpose. The conductive layer 4 can be used to electrically connect the disconnected area R in the first patterned metal layer 21 or the disconnected area R in the second patterned metal layer 22.

The conductive layer 4 is a first conductive layer 41 when the conductive layer 4 is a single-layer structure. As shown in FIG. 3 and FIG. 4A, in an embodiment of the present disclosure, laser chemical vapor deposition (LCVD) can be performed with a raw material such as, but are not limited to, tungsten hexacarbonyl (W(CO)₆) after forming a through hole 5 in the first metal section M1 or second metal section M2 by illuminating the first metal section M1 or the second metal section M2 with laser, such that tungsten is deposited in the through hole 5 and then a wiring is formed to electrically connect the first metal section M1 or the second metal section M2. Herein, the first conductive layer 41 can be at least partially in contact with the first metal section M1 or second metal section M2, provided that the goal of electrical connection can be achieved. In another embodiment of the present disclosure, the raw material of chemical vapor deposition may, by way of example and not limitation, be cobalt, chromium, titanium, titanium nitride, another suitable metal, or a combination thereof.

Therefore, as shown in FIG. 3 and FIG. 4A, the electronic device according to the present disclosure comprises: a substrate 1; a second patterned metal layer 22 comprising a first metal section M1 and a second metal section M2 disconnected to the first metal section M1, wherein at least one of the first metal section M1 and the second metal section M2 has a through hole 5; and a first conductive layer 41 electrically connected with one of the first metal section M1 and the second metal section M2 by the through hole 5; wherein the first conduction layer 41 has a protrusion 6 locating outside the through hole. Herein, a second patterned metal layer 22 serves exemplary purposes in FIG. 4A, but the present disclosure is not limited thereto. In another embodiment of the present disclosure, the second patterned metal layer 22 can be replaced by the first patterned metal layer 21, and the other laminated structures can be adjusted if necessary.

More specifically, as shown in the cross-section of FIG. 4A, the first conductive layer 41 can have a minor roughness, so that the bottom of the through hole 5 has a width W perpendicular to the normal direction of the substrate 1; a first height H1 is the maximum height from the top surface 411 of the first conductive layer 41 to the substrate surface 11 in a first area P1, which is defined with the width W starting from the edge of the through hole 5; and a second height H2 is the maximum height from the top surface 411 of the first conductive layer 41 to the substrate surface 11 in a second area P2, which is defined with the width W starting from the edge of the first area P1; wherein the first area P1 is located adjacent to the through hole 5, the first area P1 is located between the second area P2 and the through hole 5, and the first height H1 is greater than the second height H2. Said protrusion 6 is a structure corresponding to the first height H1 and the protrusion 6 is located in the first area. As a result, the first conductive layer 41 has different thicknesses in the normal direction of the substrate 1. Since the thicker region has better conductivity, the protrusion 6 can be disposed adjacent to the turning in the wiring or the region where the slope changes, thereby improving the characteristics of stable conductivity or durability.

In another embodiment of the present disclosure, a laser illumination is performed on the first metal section M1 or the second metal section M2 to form a conductive layer 4 after forming a through hole 5 on the first metal section M1 or the second metal section M2, and the conductive layer 4 may be formed by the step of laser curing or thermal curing, for example, comprising a conductive paste (such as silver paste) having smaller-impedance, wherein, at least a portion of the conductive layer 4 is disposed in the through hole 5 and electrically connected to the first metal section M1 or the second metal section M2. In another embodiment of the present disclosure, the material of the conductor layer 4 may comprise conductive paste of other materials, such as gold paste or other polymer paste containing conductive compositions. However, the present disclosure is no limited thereto. The advantage of using conductive paste is that its material selectivity is diversified, and it can provide excellent contact with metal sections using its good ductility, adhesion or coverage, thereby improving the stability of conductivity for the repaired wiring. The silver paste serves exemplary purpose in the following embodiment, but the present disclosure is not limited thereto. The material thereof is subject to no particular limitation, provided that it meets the needs of conductivity and good contact with metal sections or interlayers of the conductive layer.

Herein, the depth of the through hole 5 is subject to no particular limitation, provided that the through hole 5 enables the first metal section M1 or the second metal section M2 to be electrically connected with the conductively layer 4. For example, the through hole 5 does not penetrate the first insulating layer 31, that is, the subsequently formed conductive layer 4 can be disposed on the first insulating layer 31 when repairing the second patterned metal layer 22 of FIG. 4A.

The conductive layer 4 can comprise a second conductive layer 42 and a third conductive layer 43 when the conductive layer 4 is a multi-layer structure. As shown in FIG. 3 and FIG. 4B according to an embodiment of the present disclosure, LCVD, taken for example, can be performed after forming a through hole 5 in the first metal section M1 or second metal section M2 by illuminating the first metal section M1 or the second metal section M2 with laser, such that tungsten is deposited in the through hole 5 and the second conductive layer 42 is formed to electrically connect with the first metal section M1 or the second metal section M2. Then, a third conductive layer 43 may be formed, for example, with a conducting paste (such as silver paste) having smaller-impedance and the third conductive layer 43 is formed by laser curing or thermal curing, such that the first metal section M1 is electrically connected with the second metal section M2 by the third conductive layer 43, the first metal section M1 is electrically connected with the second metal section M2 by the second conductive layer 42, or the first metal section M1 is electrically connected to the second metal section M2 by the second conductive layer 42 and the third conductive layer 43.

Herein, the present disclosure does not impose particular limitations on the materials of the second conductive layer 42 and third conductive layer 43. For example, the second conductive layer may be formed with a conducting paste, and then the third conductive layer 43 may be formed by LCVD, which deposits a metal layer. However, the present disclosure is not limited thereto. In an embodiment of the present disclosure, the material of the third conductive layer 43 may be selected from the material having smaller impedance value than that of the second conductive layer 42. However, the present disclosure is not limited thereto. In addition, the second conductive layer 42 can be at least partially in contact with the first metal section M1 or second metal section M2; and the second conductive layer 42 is subject to no particular limitation, provided that the second conductive layer 42 can electrically connect to the first metal section M1 or second metal section M2. Likewise, the second conductive layer 42 can be at least partially in contact with the third conductive layer 43.

The charge-transfer barrier of interface, caused by different materials or manufacturing processes, can be improved by the material selection, material matching or process adjustment of the conductor layer 4 when the conductive layer 4 comprises a plurality of layers. Thereby, the metal composition of the interface between layers (such as an interface between a metal section and conductive layer or an interface between a plurality of layers in the conductive layer) is mixed. Therefore, the electrical connection is more continuous, or oxide layer existing between the interfaces is improved to lower the impedance. In an embodiment of the present disclosure, the first metal section M1 is electrically connected with the second metal section M2 by the conductive layer 4. After the repair, the impedance value between the first metal section M1 and the second metal section M2 can be greater than 0Ω and less than or equal to 100Ω, greater than 0Ω and less than or equal to 50Ω, greater than 0Ω and less than or equal to 30Ω. However, the present disclosure is not limited thereto. By such repairing method, the disconnected area R still has excellent conductivity after repairing. In terms of display, there is no distinguishable difference displaying in the panel after driving the panel. Therefore, the yield of the display device can be increased, the cost of the display device can be reduced, or the durability of the display device can be enhanced.

Accordingly, as shown in FIG. 3 and FIG. 4B, the electronic device according to the present disclosure comprises: a substrate 1; a first patterned metal layer 21 disposed on the substrate 1, and the first patterned metal layer 21 comprises a first metal section M1 and a second metal section M2 disconnected to the first metal section M1, wherein at least one of the first metal section M1 and the second metal section M2 has a through hole 5; a second conductive layer 42, and at least a portion of the second conductive layer 42 is disposed in the through hole 5; and a third conductive layer 43 disposed on the second conductive layer 42, and at least a portion of the third conductive layer 43 is disposed in the through hole 5; wherein the second conductive layer 42 is electrically connected to the first metal section M1 or the second metal section M2. Herein, a first patterned metal layer 21 serves exemplary purposes in FIG. 4B, but the present disclosure is not limited thereto. In another embodiment of the present disclosure, the first patterned metal layer 21 can be replaced by the second patterned metal layer 22.

Herein, as shown in FIG. 4B, the through hole 5 can penetrate the first insulating layer 31, and at least a portion of the conductive layer 4 can be in touch with the substrate surface 11. Therefore, in an embodiment of the present disclosure, the second conductive 42 can be in touch with the substrate surface 11. Furthermore, in an embodiment of the present disclosure, the conductive layer 4 can have at least two different widths in the top view direction, as shown in FIG. 3. For example, but not limited to, a turning of a wiring is subject to have a larger width when the first conductive layer 41 or the second conductive layer 42 (or the third conductive layer 43 described hereinafter) forms the wiring, such that the conductive layer 4 provides stable or excellent conductivity regardless the bending route, as shown in disconnected position C-F of FIG. 3.

Referring to FIG. 4C, it can be seen that FIG. 4C is similar to FIG. 4B, wherein the differences between the two are listed below. Compared to FIG. 4B, the cross-sectional view shown in FIG. 4C further comprise a first conductive layer 41 locating outside the through hole 5, and the first conductive layer 41 is disposed under the second conductive layer 42.

More specifically, as shown in FIG. 3 and FIG. 4, the conductive layer 4 can comprise a first conductive layer 41, a second conductive layer 42 and a third conductive layer 43 when the conductive layer is multi-layer structure. In an embodiment of the present disclosure, the first conductive layer 41 is formed after identifying a first metal section M1 and a second metal section M2 disconnected to the first metal section M1 in a first patterned metal layer 21 or the second patterned metal layer 22, and a wiring can, by way of example and not limitation, be silver paste. At least a portion of the first conductive layer 41 overlaps the first metal section M1 and the second metal section M2 in the top view direction. Afterward, illuminate the first metal section M1 or the second metal section M2 overlapping the first conductive layer 41 with laser to form at least one through hole in the first metal section M1 or the second metal section M2. Herein, the first conductive layer 41 forms a protrusion 6 outside the through hole 5 after the laser processing. Then, the second conductive layer 42 and the third conductive layer 43 are formed in sequence in the through hole 5. For instance, tungsten can be deposited, by LCVD, in the through hole 5 to form the second conductive layer 42, and the third conductive layer 43 is then formed, by the step of illuminating curing or thermal curing, with a material of silver paste. Therefore, on the outside of the through hole 5, the first conductive layer 41 can be disposed under the second conductive layer 42.

Herein, though the present embodiment uses the first conductive layer 41 to form a wiring as an example, the present disclosure is not limited thereto. For example, the second conductive layer 42 can be used to form the wiring, such that the first metal section M1 is connected with the second metal section M2 by the second conductive layer 42. Alternatively, the third conductive layer 43 can be used to form the wiring, such that the first metal section M1 is connected with the second metal section M2 by the third conductive layer 43.

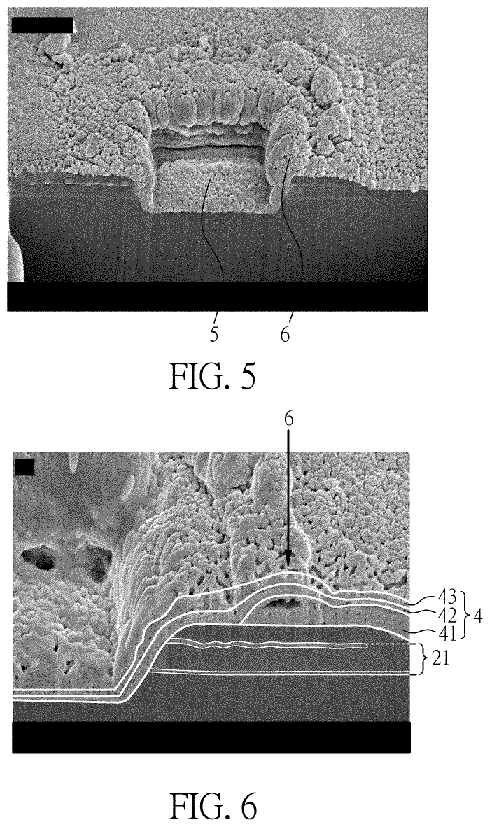

Referring to FIG. 5, FIG. 5 is a scanning electron microscope (SEM) image showing the cross-section of an electronic device according to an embodiment of the present disclosure. In such embodiment, the first conductive layer 41 is formed, for example, of tungsten. For instance, a thicker deposition layer can be formed at the outer edge of the through hole 5 in LCVD process, thereby forming a protrusion 6. This protrusion 6 can increase the conductivity of the conductor layer 4 which enters into the climbing area from the through hole 5, thereby improving the repairing effect.

Referring to FIG. 6, FIG. 6 is a scanning electron microscope (SEM) image showing the cross-section of an electronic device according to another embodiment of the present disclosure. In this embodiment, for example, it can be observed at protrusion 6 (indicated with an arrow) that a third conductive layer 43, a second conductive layer 42, and a first conductive layer 41 are located in sequence from the outermost layer to the inner layer. In an embodiment of the present disclosure, the material of the first patterned metal layer 21 or the second patterned metal layer 22 can be a single-layer or multi-layer structure comprising molybdenum or aluminum. To analyze the composition and proportion at the structure of protrusion 6 (indicated with an arrow), transmission electron microscopy (TEM) can be performed. In some embodiments, it can be observed that the metal composition of the interface in the conductive layer 4 is in mixed status, which is a continuous and gradual distribution. The TEM analysis shows that the repairing method has special effects including excellent contact and improving the interface to be in a continuous and gradual distribution, thereby achieving smaller impedance, high reliability, or high repair success rate. In addition, when the first conductive layer 41 forms a wiring, it can have at least two different widths in a top view direction, according to an aspect of the present disclosure, as shown in FIG. 3. For example, a turning of the wiring is subject to have a larger width, such that the conductive layer 41 provides stable or excellent conductivity regardless the bending route

Herein, the first conductive layer 41, the second conductive layer 42, and the third conductive layer 43 are subject to no particular limitation and can be manufactured by the aforementioned materials; and the details are omitted. Further, the metal of the interface between layers is in mixed status when the conductive layer 4 comprises a plurality of layers, thereby making the electrical conduction continuous and improving the oxide layer barrier existing between the interfaces, discontinuous conduction in interlayer, or poor contact. Therefore, the impedance between metal sections or the conductive properties is lowered. The conductive paste forming process can respectively collocate with laser curing or thermal curing to cure the conductive paste. Besides, the effects of removing the metal oxide of the interface, or mixing or contacting the metal of interface between layers can be enhanced. Also, the LCVD process is favorable for converting the metal oxide into the metal layer having excellent conductivity, resulting in excellent contact for the interlayer of the conductive layer 4, thereby enhancing the conductivity. Therefore, in an embodiment of the present disclosure, a plurality of impedance values are obtained from the conductive layer 4 (length: 300 μm), and the plurality of impedance values can be greater than 0Ω and less than or equal to 30Ω, greater than 0Ω and less than or equal to 75Ω, or greater than 0Ω and less than or equal to 100Ω. However, the present disclosure is not limited thereto.

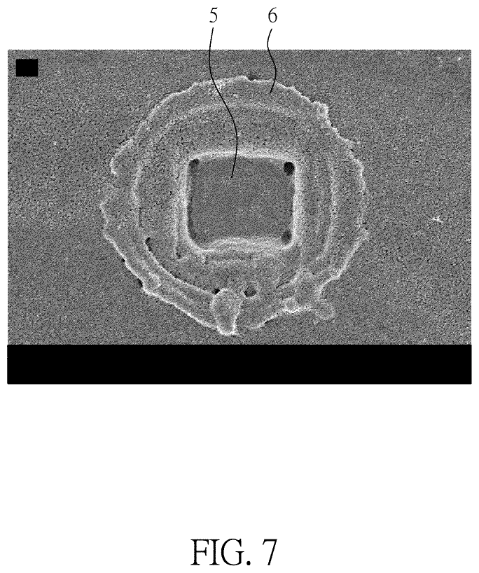

FIG. 7 is a scanning electron microscope (SEM) image showing a top view of a through hole 5 according to an embodiment of the present disclosure. As shown in FIG. 7 the protrusion 6 of the first conductive layer 41 locating outside the through hole 5 has a ring structure in a top view direction, for example. Herein, the through hole 5 is rectangular, but the disclosure is not limited thereto. For example, the through hole 5 can be circular, elliptical, trapezoidal, rhombus, or irregular, provided that the through hole 5 can be formed on a metal section by laser illuminating passing through a pattern of a photomask. In this top view, it can be found that the protrusion 6 is located outside the through hole 5 and has a characteristic of different widths. The conductive layer 4 at the through hole 5 can have better effect of electrical connection by collocating processes or materials.

In conclusion, the present disclosure provides a method for repairing substrates and an electronic device thereof, such that the conductive layer electrically connecting to the first metal section and the second metal section achieves effects of low impedance, high reliability or high repair success rate. Furthermore, the features of the embodiments described in the present disclosure can be combined with each other to form another embodiment.

The electronic device of the present disclosure can also be applied to various display devices, such as liquid-crystal (LC), organic light-emitting diode (OLED), quantum dot (QD), fluorescent material, phosphor material, light-emitting diode (LED), micro light-emitting diode, mini light-emitting diode or other display medium of a display device. However, the present disclosure is not limited thereto. In the embodiments of the present disclosure, the display device can be, for example, a flexible display, a touch display, a curved display, or a tiled display. However, the present disclosure is not limited thereto.

The present disclosure is disclosed above by preferred embodiments. However, persons skilled in the art should understand that the preferred embodiments are illustrative of the present disclosure only, but shall not be interpreted as restrictive of the scope of the present disclosure.

What is claimed is:

1. An electronic device, comprising:
a substrate;
a patterned metal layer disposed on the substrate, and the patterned metal layer comprises a first metal section and a second metal section disconnected to the first metal section, wherein at least one of the first metal section and the second metal section has a through hole; and
a first conductive layer electrically connected to one of the first metal section and the second metal section by the through hole;
wherein, the first conductive layer has a protrusion located outside the through hole.

2. The electronic device of claim 1, wherein the protrusion of the first conductive layer located outside the through hole has a ring structure in a top view direction.

3. The electronic device of claim 1, further comprising a first area located adjacent to the through hole, wherein the protrusion is located in the first area.

4. The electronic device of claim 1, further comprising a first area and a second area, the first area located between the second area and the through hole, wherein the first conductive layer has a first height in the first area, the first conductive layer has a second height in the second area, and the first height is greater than the second height.

5. The electronic device of claim 1, wherein the first conductive layer comprises a conductive paste.

6. The electronic device of claim 1, further comprising a first insulating, layer disposed between the substrate and the patterned metal layer, wherein the first conductive layer is disposed on the first insulating layer in the through hole.

7. An electronic device, comprising:
a substrate;
a patterned metal layer disposed on the substrate, and the patterned metal layer comprising a first metal section and a second metal section disconnected to the first metal section, wherein at least one of the first metal section and the second metal section has a through hole; and
a second conductive layer, at least a portion of the second conductive layer disposed in the through hole; and
a third conductive layer disposed on the second conductive layer, and at least a portion of the third conductive layer disposed in the through hole;
wherein the second conductive layer is electrically connected to the first metal section or the second metal section.

8. The electronic device of claim 7, wherein the second conductive layer is in contact with a substrate surface.

9. The electronic device of claim 7, wherein the third conductive layer has at least two widths in a top view direction.

10. The electronic device of claim 7, wherein an impedance of the third conductive layer is smaller than an impedance of the second conductive layer.

11. The electronic device of claim 7, wherein the second conductive layer and the third conductive layer comprises a conductive paste or metal.

12. The electronic device of claim 7, wherein the second conductive layer is at least partially in contact with the third conductive layer.

13. The electronic device of claim 7, further comprising a first conductive layer, wherein the first conductive layer is disposed under the second conductive layer and outside the through hole.

14. The electronic device of claim 13, wherein the first conductive layer has at least two different widths in a top view direction.

15. The electronic device of claim 13, wherein the first conductive layer has a protrusion located outside the through hole.

16. The electronic device of claim 15, wherein the protrusion of the first conductive layer has a ring structure in a top view direction.

17. The electronic device of claim 13, wherein at least a portion of the first conductive layer overlaps the first metal section and the second metal section in a top view direction.

18. The electronic device of claim 13, wherein the first conductive layer comprises a conductive paste or metal.

19. A method for repairing substrates, comprising:
providing a substrate having a patterned metal layer disposed thereon;
identifying a first metal section and a second metal section disconnected to the first metal section in the patterned metal layer;
illuminating at least one of the first metal section and the second metal section with laser to form at least one through hole in at least one of the first metal section and the second metal section;
forming a second conductive layer, at least a portion of the second conductive layer disposed in the through hole, and the second conductive layer electrically connected to the first metal section or the second metal section; and
forming, a third conductive layer on the second conductive layer, and at least a portion of the third conductive layer disposed in the through hole.

20. The method of claim 19, wherein an impedance of the third conductive layer is smaller than an impedance of the second conductive layer.
